(19) United States
(12) Patent Application Publication
(10) Pub. No.: US 2015/0056734 A1
(43) Pub. Date: Feb. 26, 2015

(54) METHOD FOR SEPARATION BETWEEN AN ACTIVE ZONE OF A SUBSTRATE AND ITS BACK FACE OR A PORTION OF ITS BACK FACE

(71) Applicant: COMMISSARIAT A L'ENERGIE ATOMIQUE ET AUX ENE ALT, Paris (FR)

(72) Inventors: Laurent Grenouillet, Rives Sur Fure (FR); Maud Vinet, Rives Sur Fure (FR)

(73) Assignee: COMMISSARIAT A L'ENERGIE ATOMIQUE ET AUX ENE ALT, Paris (FR)

(21) Appl. No.: 14/445,228

(22) Filed: Jul. 29, 2014

(30) Foreign Application Priority Data
Aug. 20, 2013 (FR) 13 58080

(51) Int. Cl. H01L 21/762; H01L 31/18

(52) U.S. Cl. CPC H01L 21/76224; H01L 21/7624; H01L 31/18
USPC 438/57; 438/424

(57) ABSTRACT

A Method for making a separation between an active zone of a substrate located on its front face from a given portion of the substrate located on its back face, wherein trenches and cavities wider than the trenches are formed to extend said trenches, such that at least one given cavity formed to extend a given trench is adjacent to another cavity, and when the cavities have been filled with a given material, they form a separation zone between said active zone and a given portion of the substrate that will be removed later.

### TECHNICAL FIELD AND PRIOR ART

This invention relates to microelectronics and is more particularly applicable to the field of microelectronic device fabrication methods.

There are increasing and ongoing attempts in this field to reduce the size of devices while increasing the integration density of their components.

One particular way of achieving this is to make so-called “3D” devices composed of stacks of substrates each with a so-called “active” layer, in other words in which components are at least partially formed.

An attempt to reduce the total thickness of these stacks can be made by stacking only the active layers of substrates that are generally thin, for example less than 100 μm, by removing a part of these substrates that is or has become useless, the total thickness of which may exceed several hundred of micrometres and for example is between 400 μm and 800 μm.

One known technique for dissociating an active layer of a substrate from a layer that was used as a support consists of making an implantation, for example based on hydrogen, between this active layer and this support layer so as to create a weakened zone and to be able to separate the active layer at this weakened zone, for example by heat and/or mechanical treatment.

Documents US 2005/0148163 A1, US 2008/0064182 A1 and WO 2009/069709A1 disclose examples of fabrication methods using such a technique, in which a handle substrate bonded to the active layer can be used to facilitate detachment of the active layer from the support layer.

One particular disadvantage of this technique is that it generates defects in the active layer, particularly as a result of the implanted species passing through this active layer.

Another separation technique is applicable to semiconductor on insulator type substrates, in other words substrates with a support layer covered by an insulating layer, itself covered by a semiconducting layer that will form an active layer.

This other technique consists of etching the support layer until the insulating layer is reached, for example by grinding and then by etching making use of the insulating layer as the stop layer.

However, the disadvantage of this type of method is that it entirely eliminates the support layer, which can be very expensive. Moreover, it cannot be applied to devices in which the support layer comprises a useful part, in other words a part in which at least one active or passive element will be at least partially formed.

Therefore, the problem arises of finding a new microelectronic method that does not have the disadvantages mentioned above, and that can dissociate the active layer of a substrate from another portion of the substrate acting as support in order to thin this substrate.

More generally, the problem arises of finding a new method for making a separation zone between the active layer of a substrate and another portion of the substrate acting as support.

### PRESENTATION OF THE INVENTION

An embodiment of the invention concerns a method for making a separation and possibly isolating an active zone of a substrate located on its front face, from a portion of the substrate located on its back face and acting as support.

An embodiment thus relates to a method of manufacturing a microelectronic device comprising consisting of:
making a plurality of trenches on the front face of a substrate, comprising an active zone in which one or several components are provided,
forming cavities wider than the trenches to extend said trenches, such that at least one given cavity formed to extend a given trench is made adjacent to another cavity formed to extend another trench adjacent to said given trench,
filling said cavities with at least one given material.

A trench means a cavity extending approximately perpendicular to the principal plane of the substrate.

Cavities wider than the trenches means a cavity for which the dimensions in the plane of the substrate are larger than the dimensions of the trench.

The cavities full of the given material form a separation between said active zone and a given portion of the substrate located on its back face and formed from a material different from said given material.

Advantageously, all cavities formed may be such that at least one given cavity formed to extend a given trench opens up laterally into another cavity adjacent to said given cavity, and with this other cavity forms a tunnel in said substrate filled with the given material, said other cavity being formed as an extension to another trench adjacent to said given trench.

In this case, the tunnel full of the given material forms a continuous separation between said active zone and a given portion of the substrate based on another material different from said given material and located on the back face of the substrate opposite said front face.

A method for dissociating the active zone of the substrate from a given portion of the substrate located on its back face is further provided.

To achieve this, a given portion of the substrate facing said trenches and on the back face of the substrate opposite said front face is removed after the cavities have been filled, said portion being based on another material different from said given material.

This invention also allows for the use of a new method of thinning a substrate from its back face.

To achieve this, the method may further include a step after the cavity filling step consisting of removing said given portion of the substrate.

Such a method may be used on a semiconductor on insulator type substrate such as an SOI substrate.

When used on a semiconductor on insulator substrate, such a method can be used to remove a portion from the back face of the substrate while keeping the insulating layer of the substrate, which may for example be a buried oxide layer in the case of an SOI substrate.

Such a method can also be used to remove a portion from the back face of a semiconductor on insulator substrate, while keeping a part of its semiconducting support layer located under the insulating layer of the substrate.

The method may also be applied to other types of substrates, for example bulk substrates.

According to a first possible embodiment of the step to remove said given portion of the substrate, this step comprises selective etching of said other material of the substrate relative to said given cavity infill material, or removal of said other material of the substrate, particularly by etching or planarizing, until said given cavity infill material on the back of the substrate is reached, said given material then acting as a stop material to said etching or said planarizing.

Planarization means an essentially mechanical step that also includes grinding and that may possibly be chemically assisted.

Advantageously, said given portion of the substrate may be removed by:
forming of a mask protecting a given zone of the back face of the substrate, another zone of the back face being exposed, then
etching of this other zone through the mask.

A portion of the back face of the substrate can thus be removed without etching the entire back face.

The method may further include a step of planarizing said given material on the back face of the substrate after removal of said portion.

After removing a portion from the back face of the substrate, this back face can thus be prepared exposing the given material ready for subsequent deposit of one or several layers or an assembly with another support.

The method may then also include a step after planarisation of said given material, consisting of depositing at least one layer on the side of the back face of the substrate, for example an anti-reflecting layer if an optical device is being made.

As a variant, the method may include a step after planarisation of said material to assemble a support on the back face of said substrate, for example by direct bonding.

According to one possible embodiment of the method, the given infill material can be removed after having removed said given portion of the substrate.

This infill material can then be replaced by a material with different properties, for example a conducting material.

As a variant, the infill material is removed so as to expose blocks of the substrate with a shape complementary to the shape of the cavities, for example pyramid-shaped, these blocks being designed to form dioptres, and particularly lenses.

According to a second embodiment of the step to remove said given portion of the substrate in which the cavities are made such that one or several of the cavities open up laterally on a zone in a side face of the substrate, the removal may be done by selective etching of said given material relative to said other material.

The active zone and the given portion of the substrate may be separated by removing the cavity infill material.

According to one possible embodiment of the method, the step to remove said given portion of the substrate may be done using a so-called “full wafer” removal when the area of said portion removed on the back face is equal to the total area of the front face measured parallel to the principal plane of the substrate.

According to one possible embodiment of the method, the steps consisting of making said trenches, forming said widened cavities and filling said cavities may be done in several sequences and include the following:
make a first plurality of trenches on the front face of the substrate,
form first cavities wider than first trenches to extend said first trenches,
fill in said first cavities using said given material,
make a second plurality of trenches on the front face of the substrate,
form second cavities wider than the second trenches to extend said second trenches,
fill in said second cavities using said given material.

Trenches and cavities are made in several steps particularly when it is required to make a “full wafer” removal of a portion of the substrate. In this embodiment, the production of trenches and cavities in several steps provides a means of achieving mechanical cohesion of all blocks in the substrate around which the trenches and cavities were made using the infill material for the first trenches and the first cavities. The first trenches and the first cavities filled with a given material thus form means of providing mechanical support to blocks of the substrate around which the trenches and cavities were formed.

According to one possible embodiment of the method, after the cavities have been filled using said given material, a first protective layer is formed on the front face of the substrate to close said trenches.

This protective layer is designed such that the given infill material may be etched selectively with regard to the material of said protective layer.

It is thus possible to etch the given infill material through the back face of the substrate while protecting its front face.

According to one possible embodiment, the given infill material of said cavities may be annealed to increase its density after the cavities have been filled and before said portion of the substrate has been removed.

This annealing may reinforce cohesion of the cavity infill material.

According to one possible embodiment, a handle substrate may be assembled on the front face of the substrate after the cavities have been filled and before said portion of the substrate has been removed.

According to one possible embodiment of the method, the given trench and said adjacent trench may have a predetermined spacing p. The cavities can then be formed by etching the substrate such that the cavities comprise walls forming a tapered shape, this etching being prolonged such that the distance Δ separating the walls is equal to a value such that Δ>p.

According to one particular embodiment of the method, the portion removed from the substrate may be based on Si and have a ‘(100)’ crystallographic orientation. In this case, the cavities may be formed by etching along the ‘(111)’ crystallographic plane.

Cavities with walls inclined at a predetermined angle from the principal plane of the substrate can thus be made, for example of the order of 52°.

According to one possible embodiment, the given cavity infill material may be a dielectric material like SiO₂.

In this case, tunnels full of dielectric material are used to make electrical isolation between the active zone and said given portion of the substrate.

As a variant, the given cavity infill material may be a metal. The method can then also comprise a step after formation of the cavities and before they are filled, to form a barrier diffusion layer lining the walls of the cavities.

According to one possible embodiment, several of said cavities may be located at different depths in the substrate.

This also makes it possible to remove a given portion of the substrate over a thickness that is not constant.

The method according to the invention may for example be applicable for fabrication of an imaging device.

### BRIEF DESCRIPTION OF THE DRAWINGS

This invention will be better understood after reading the description of example embodiments given purely for information and in no way limitative, with reference to the appended drawings in which:

FIGS. 1A-1K show a first example of a method for forming an isolating separation zone between an active layer of a substrate and a given portion of said substrate acting as support;

FIGS. 2A-2C show a set of possible steps in the method following the first example of the method, to thin said substrate by removing said given portion;

FIGS. 3A-3E show a second example of the method, to separate an active layer of a substrate and a portion of said substrate acting as support, the separation being made by selective etching of an infill material for cavities formed in the substrate;

FIGS. 4 to 7 show different variant embodiments of cavities formed in a substrate for separating an active layer of the substrate and a portion of this substrate acting as support;

FIGS. 8A-8D show a third example of the method to separate an active layer of a substrate in which components were formed and a given portion of said substrate acting as support, the separation being made by removal of said given portion until reaching cavities formed in the substrate and filled with a given material;

FIG. 9 shows a variant embodiment of the third example of the method wherein, after a portion of the back face of the substrate has been removed, another support is affixed onto this back face;

FIG. 10 shows another variant embodiment of the third example of the method wherein, after a portion of the back face of the substrate has been removed, a layer is deposited on this back face;

FIG. 11 shows another variant embodiment of the third example of the method wherein, after a portion of the back face of the substrate has been removed, the cavity infill material is removed;

FIG. 12 shows another variant embodiment of the third example of the method wherein, after a portion of the back face of the substrate has been removed, the given cavity infill material is removed and this given material is replaced by another material with different properties;

FIGS. 13A-13B show an example of the method of thinning a portion of the back face of a substrate;

FIG. 14 shows a variant of the method of thinning a central zone of a substrate on its back face, while keeping a peripheral zone around the central zone;

FIGS. 15A-15B show a variant of the method of thinning the back face of a substrate;

Identical, similar or equivalent parts of the different figures have the same numeric references to facilitate comparisons between the different figures.

The different parts shown in the figures are not necessarily at the same scale, to make the figures more easily readable.

### DETAILED PRESENTATION OF PARTICULAR EMBODIMENTS

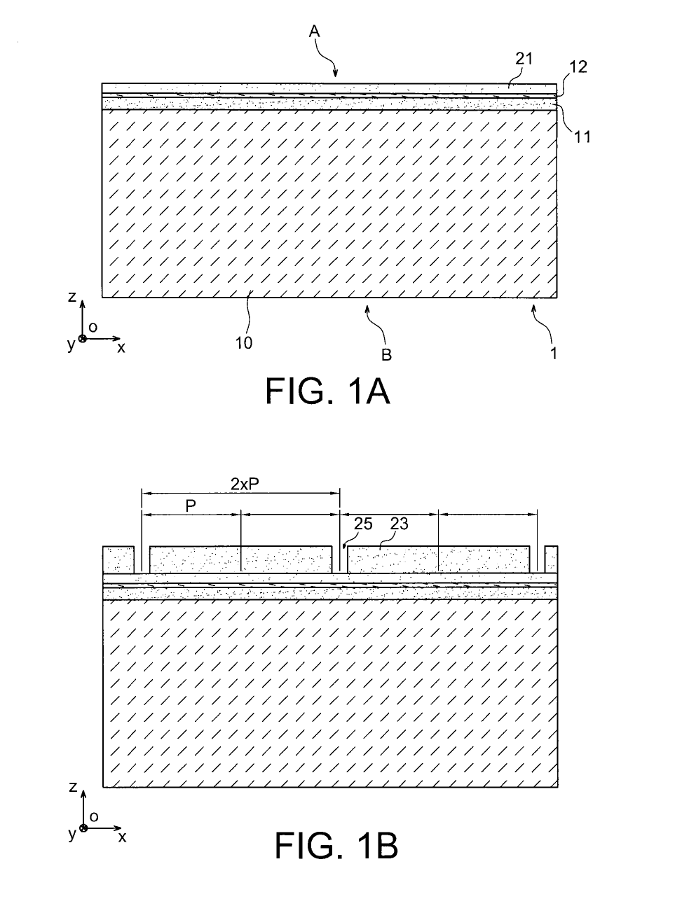

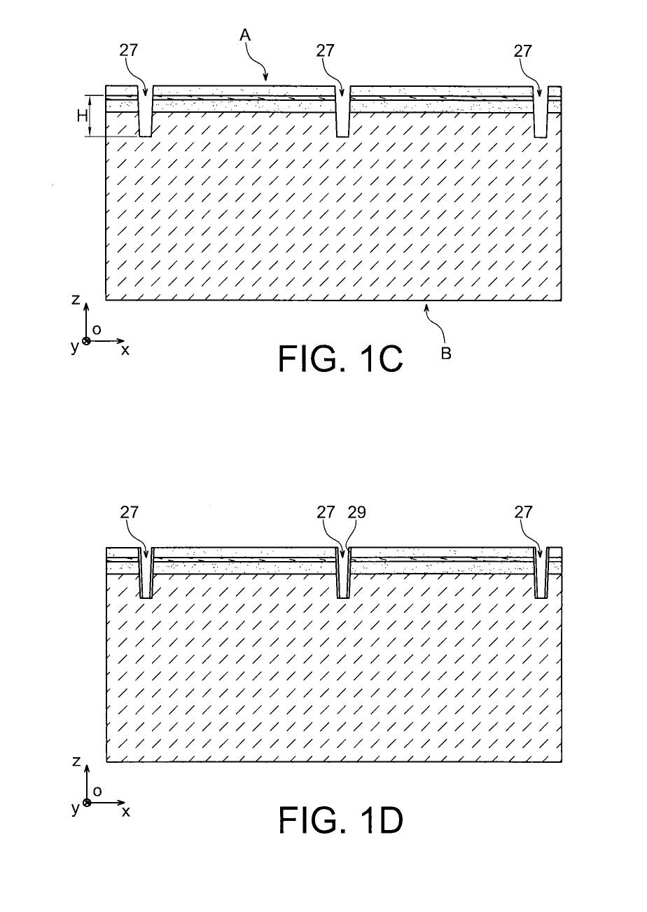

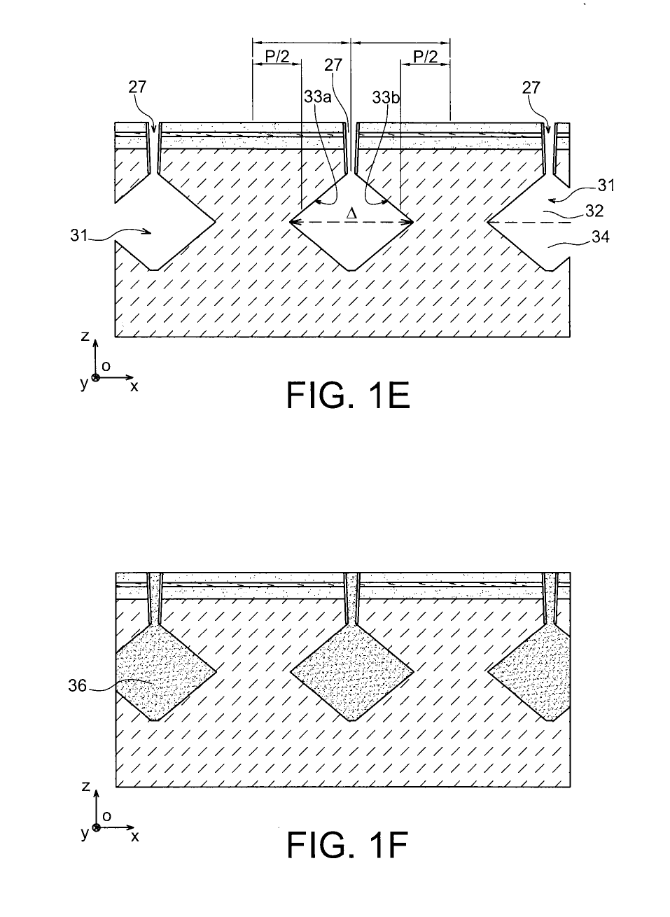

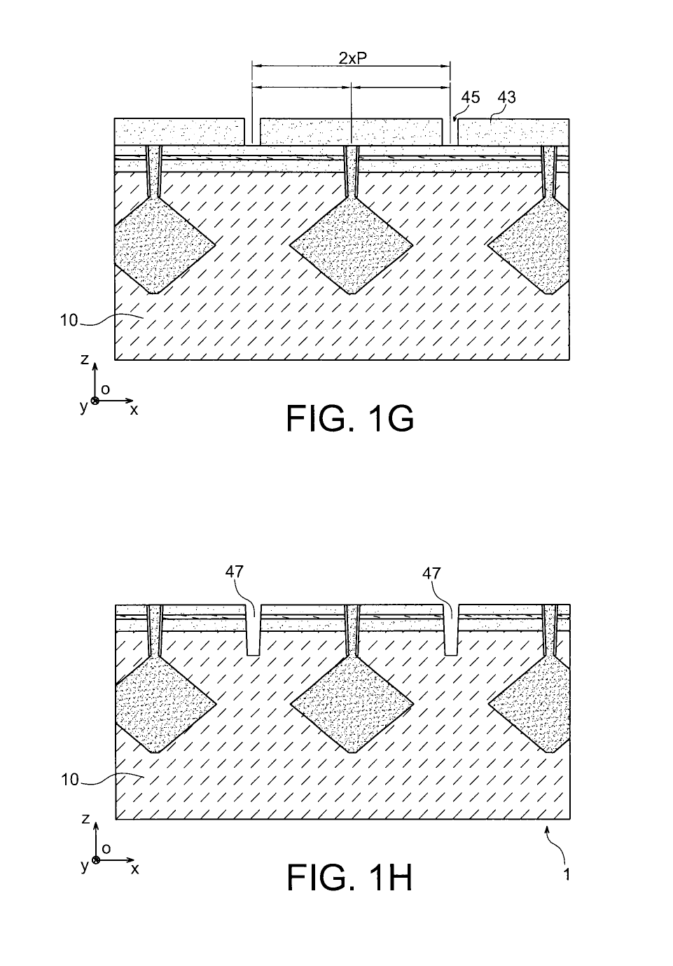

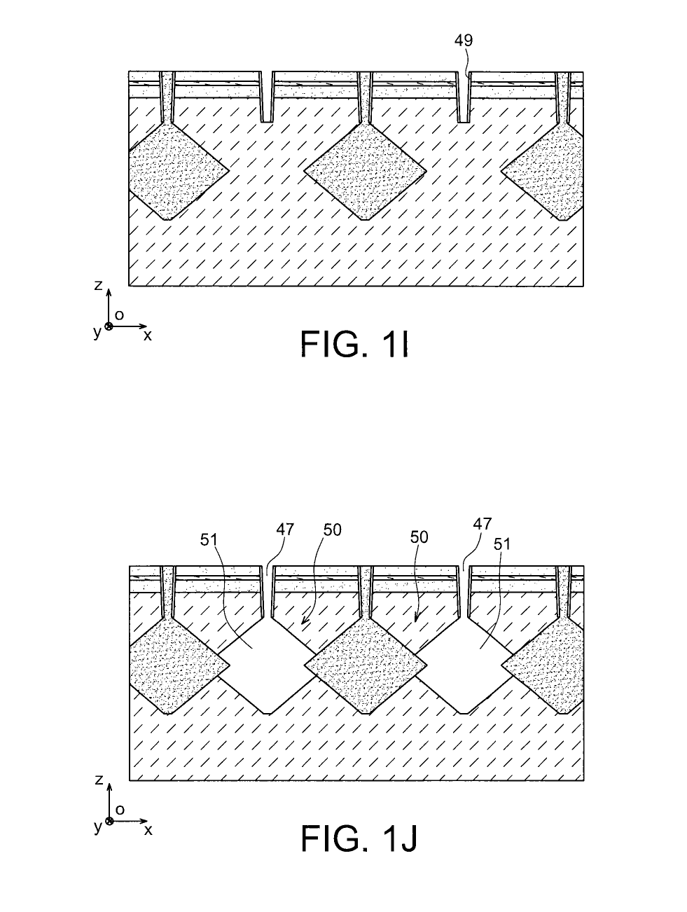

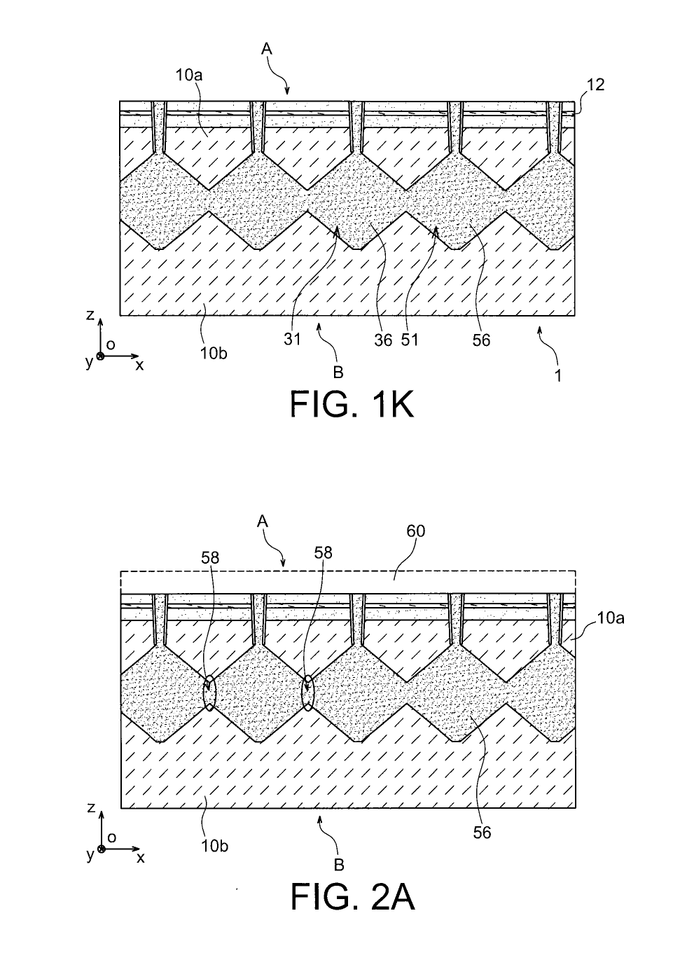

A first example method according an embodiment of the invention will now be described with reference to FIGS. 1A-1K.

The initial material for this method may for example be a semiconductor on insulator (SOI) type substrate.

The substrate 1 thus comprises a support layer, for example a semiconducting layer 10 that may be based on Si, for example between 400 μm and 1 mm thick (measured along a direction parallel to the z axis of a orthogonal coordinate system [O;x;y;z] given in FIG. 1A).

The substrate 1 may also include an insulating layer 11, for example based on silicon oxide, located on and in contact with the support layer 10. The insulating layer 11 may for example be of the BOX (Buried Oxide) type with a thickness for example of the order of 145 nm, or of the TBOX (Thin Buried Oxide) type with a thickness for example of the order of 10 nm to 25 nm.

The substrate 1 also comprises a semiconducting layer 12 called the “surface layer” located on and in contact with said insulating layer 11. This superficial semiconducting layer 12 may for example be less than 20 nm thick, and it will form an active layer on which components or parts of components will be fitted, for example transistors.

A first step (FIG. 1A) is to form a hard mask layer 21, for example based on SiₓN_{y}, on the superficial semiconducting layer 12.

Then (FIG. 1B), a mask 23 is formed on the hard mask layer 21 based for example on a photosensitive resin comprising openings 25 at a predetermined pitch. The distribution pitch of the openings 25 may for example be equal to 2*P, where P is a distribution pitch for trenches that will be made in the substrate 1 later, and P may for example be between 100 nm and 10 μm, for example of the order of 1 μm.

Then (FIG. 1C), etching is done through the openings 25 of the mask 23, so as to make one or several first trenches 27 passing through one face A of the substrate 1 that is longitudinal and is called “front face”. The first trenches 27 penetrate into the thickness of the support layer 10 and may for example be of the STI (Shallow Trench Isolation) type and have depth H (measured along a direction parallel to the z axis of the [O;x;y;z] orthogonal coordinate system) for example between 20 nm and 10 μm, for example of the order of 200 nm or 300 nm. The first trenches 27 are spaced at a pitch equal to 2*P.

A protective layer 29 (FIG. 1D) is then formed on the vertical walls of the trenches 27, this layer being arranged such that the bottom of the trenches 27 is not protected and thus exposes the support layer 10 of the substrate 1. The protective layer 29 is based on a material chosen such that the semiconducting material of the support layer 10 can be selectively etched relative to the material used for the protective layer 29. For example in the case in which the support layer 10 is based on silicon, the protective layer 29 may be based on a dielectric material such as SiₓN_{y} or SiO₂, or HfO₂. The protective layer 29 may be made by deposition, for example using an ALD (Atomic Layer Deposition), type technique followed by etching at the bottom of the trenches 27, for example using a plasma to expose the bottom of the trenches 27. The protective layer 29 may for example be between 3 nm and 20 nm thick.

The first cavities 31 are then formed, extending the first trenches 27 (FIG. 1E). These first cavities 31 are made so as to comprise a first part 32 that is tapered or is wider than the first trenches 27. The first part 32 of the cavities 31 will thus have a cross-section (measured along a direction parallel to the principal plane of the substrate, the principal plane of the substrate being defined herein and in the remainder of the description as being a plane passing through the substrate and parallel to the [O,x,y] plane indicated in FIG. 1E) that increases from a zone located at the junction with the trenches 27 towards another zone at a greater depth in the support layer 10 (in this case the depth being measured from the front face A of the substrate 1).

In the example embodiment shown in FIG. 1E, the cross-section of the first portion 32 of the cavities increases linearly along an axis orthogonal to the principal plane of the substrate 1 and in the direction from the front face A towards a face B of the substrate 1 opposite the front face and called the “back face”. Thus, the first part 32 of the cavities 31 comprises walls 33a, 33b inclined at a non-zero angle, for example of the order of 52° with a plane parallel to the principal plane of the substrate 1.

For example, this shape of cavities 31 may be obtained when the support layer 10 is made of silicon with a <100> crystallographic orientation, and etching is done along the <111> plane. For example, this etching may be done using HCl in the gas phase or BHF—NH₄OH in the liquid phase, or KOH or TMAH.

Etching to make the cavities 31 is advantageously prolonged such that the first tapered part 32 has a width Δ between its walls 33a, 33b (dimension of the cavities measured along a direction parallel to the principal plane of the substrate) such that Δ>P.

The cavities 31 may also have a second part 34 that is symmetric in shape with the first part 32 about an axis parallel to the principal plane of the substrate 1.

The next step (FIG. 1F) is to fill in the trenches 27 and cavities 31 using a given material 36 different from the material used in the support layer 10.

In this example embodiment, the given infill material 36 is chosen such that the semiconducting material of the support layer 10 may be etched selectively relative to this material 36. The given material 36 may be a dielectric material, for example such as SiO₂ or a low-K dielectric such as SiOC, or HfO₂. A spin-coating deposition or a method using the HARP™ (High Aspect Ratio Process) technology may be used to facilitate filling. A material such as HSQ (Hydrogen SilsesQuioxane) or more generally an SOG (Spin On Glass) type of material may also be envisaged.

Finally, a densification annealing of the infill material 36 can be made. This annealing may be done at a temperature defined as a function of the infill material 36 used, and may be between 300° C. and 1100° C., for example it may be of the order of 1050° C. for a duration for example of the order of 30 minutes when the given material 36 is SiO₂.

The next step is form a second mask 43 comprising openings 45 facing unetched zones of the support layer 10 with spacing between them equal to a pitch of 2*P (FIG. 1G).

The next step is to etch the substrate 1 through openings 45 in the mask 43 so as to form one or several second trenches 47, the bottom of which is located in the support layer 10 of the substrate 1. The mask 43 may then be removed (FIG. 1H).

The next step is to form a protective layer 49 on the vertical walls of the second trenches 47, similar to the protective layer 29 made for the first trenches 27 (FIG. 11).

Second cavities 51 are then made in extension of the second trenches 47 (FIG. 1J). The shape of the second cavities 51 may be similar to the shape of the first cavities 31 formed previously and thus comprise a first part on which the second trenches 47 open up and may be a tapered or widened shape with increasing cross-section. The spacing between the second trenches 47 and the first trenches 27 is chosen such that the second cavities 51 communicate with the first adjacent cavities 31 made previously. The second cavities 51 are thus etched such that the second cavities 51 open up on the infill material 36 of the previously made adjacent first cavities 31.

The infill material 36 of the first trenches 27 and the cavities 31 provides mechanical support to blocks 50 of the substrate around which the second trenches 47 and the second cavities 51 are made.

Then (FIG. 1K), the second cavities 51 are filled with a given material 56 that may be similar or identical to the infill material 36 of the first cavities 31. As a variant, the infill material 56 of the second cavities may be different from the infill material 36 of the first cavities. Nevertheless, it may be advantageous in this case for this material 56 to have etching properties similar to the etching properties of the material 36, particularly concerning selectivity of etching relative to the material of the support layer 10.

Filling may be followed by a planarization step using chemical-mechanical planarization (CMP) to remove the infill material 56, if there is any, located on the front face A of the substrate 1.

Annealing in order to increase the density of the infill material 56 may then be done. This annealing seals the zones 58 in materials 36 and 56 located at the junction between adjacent cavities.

Thus, we have used cavities 31, 51 communicating with each other in the support layer 10 of the semiconducting substrate, to form a tunnel filled with at least one given material 36, 56, different from the material used for the support layer.

This tunnel forms a separation between a given portion 10b of the support layer 10 located on its back face and another portion 10a of this support layer on which the thin semiconducting layer 12 that will form an active layer is supported.

The separation tunnel may extend parallel to the plane of the substrate (i.e. measured parallel to the [O;x;y] plane in FIG. 1K) on an area equal to the area of the front face, depending on the manner in which the cavities were formed, particularly the number of cavities, their distribution pitch and their dimensions.

In this example, in which the given material 36, 56 is dielectric, the tunnel filled with material 36, 56 provides electrical isolation between the active layer and the given portion 10b of the substrate 1.

It may possibly be desirable to thin the substrate 1 through its back face B.

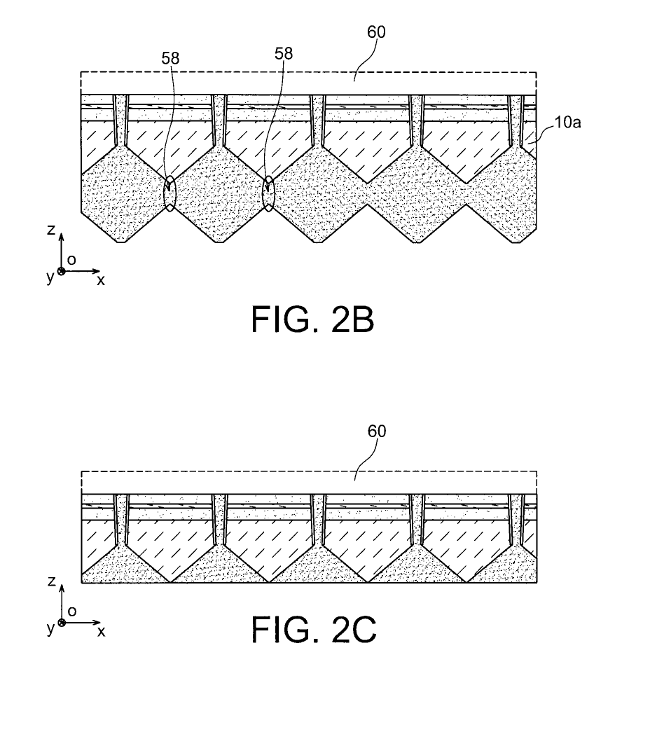

To achieve this, the next step is to form a handle support 60 on the front face A of the support 1. For example, the handle support 60 may be a deposited layer of polymer material or an insulating layer, for example based on SiO₂, made using direct bonding, in other words with no intermediate material to promote cohesion (FIG. 2A).

The next step (FIG. 2B) is to remove the given portion 10b from the support layer 10 of the substrate 1 on its back face B. This is done by applying a grinding process on the back face B, possibly combined with or followed by chemical etching, for example by means of TMAH. Etching at the back face B is continued until the infill materials 36, 56 of the cavities 31, 51 are reached, that then act as etching stop. The portion 10b removed from the support layer 10 of the substrate 1 may for example be between 100 μm and 700 μm thick.

In this embodiment, the removal made is a so-called “full wafer” removal such that the removed portion 10b extends over an area equal to the area of the front face of the substrate (measured parallel to the [O;x;y] plane in FIG. 2B).

The next step (FIG. 2C), is to perform a planarisation step on the back face B of the substrate 1 by CMP type planarizing of the infill material(s) 36, 56 of the cavities 31, 51.

A thinned substrate 1 is formed at the end of this step, in which an important part of the support layer 10 has been removed but without removing its entire thickness, since a portion 10a between the given infill material 36, 56 and the active layer is kept.

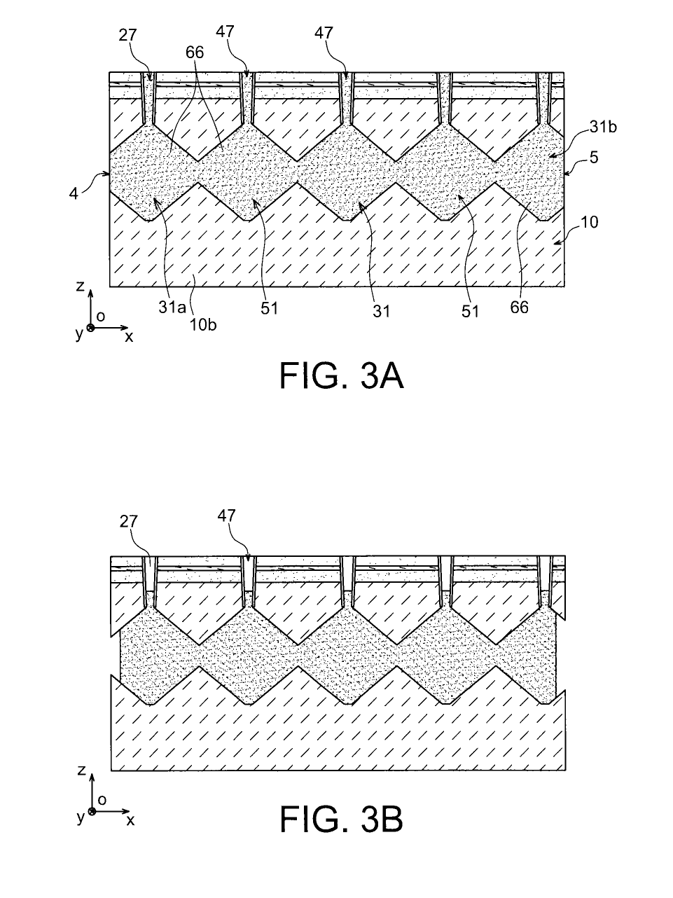

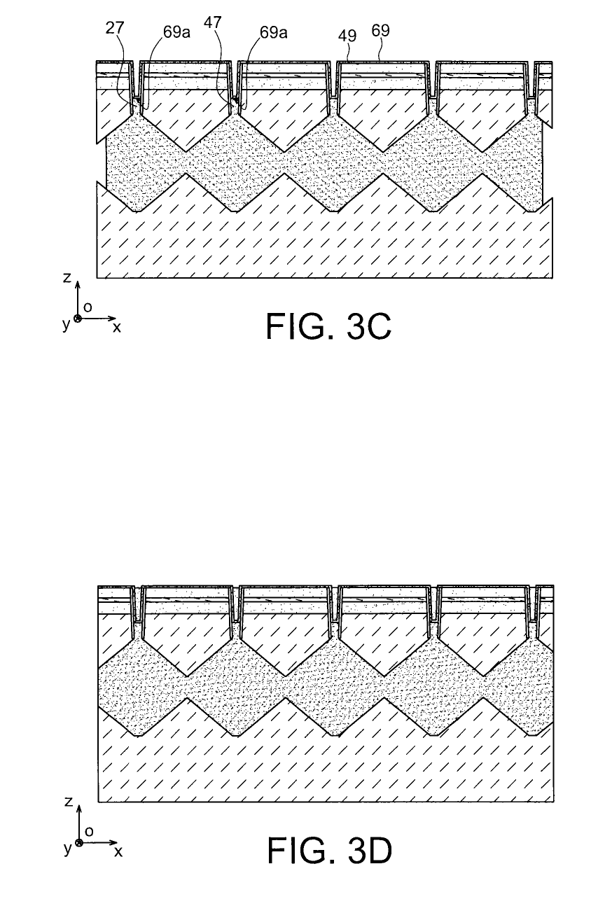

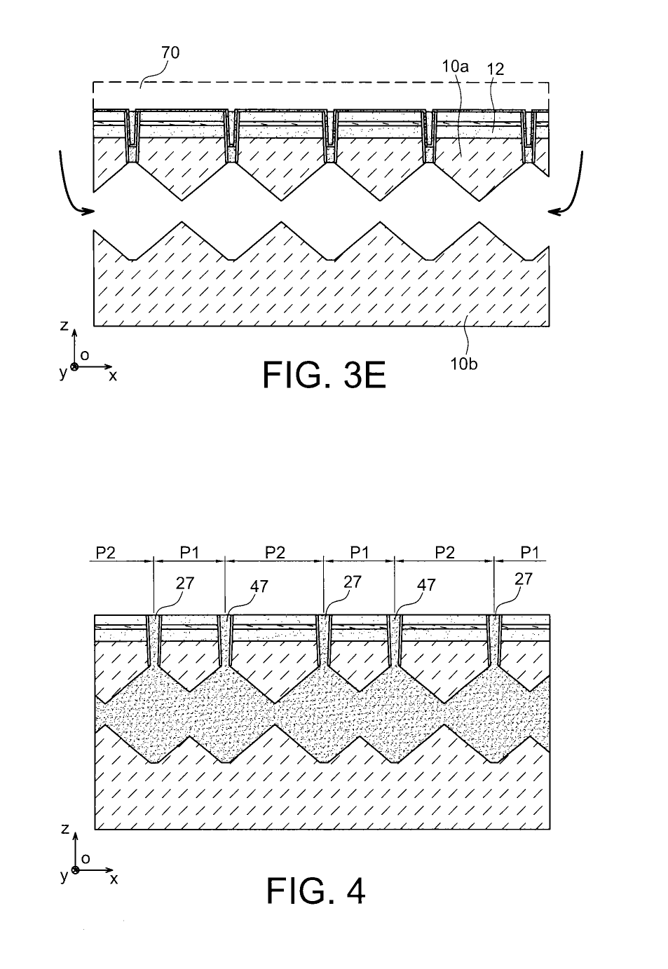

Another example embodiment is shown in FIGS. 3A-3E.

In this example, cavities formed along the extension of the trenches are made such that at least one cavity 31a and at least one other cavity 31b open up on a first zone 4 and on a second zone 5 respectively of a side face of the substrate 1, said first zone 4 and second zone 5 being located at the support layer 10.

In this example, an infill material 66 in the trenches 27, 47 and the cavities 31, 51 is chosen so that it can be selectively etched relative to the material of the support layer 10. For example, this material 66 may be SiO₂, when the support layer 10 is based on Si.

The layout of the cavities 31, 51, formed in the support layer 10 is such that they communicate with each other so as to form a continuous tunnel in the support layer 10 that extends between the first zone 4 of a lateral face of the substrate 1 and the second zone 5 of a lateral face of the substrate 1, this tunnel being filled with a material 66 that can be etched selectively relative to the material of the support layer 10 (FIG. 3A). The tunnel filled with material 66 and that extends along the longitudinal direction of the substrate, creates a separation between a portion 10a of the support layer 10 on which the active layer to be kept is supported, and a portion 10b of the support layer 10 of the substrate 1 that is to be removed.

After the trenches and cavities have been filled, a part of the infill material 66 located in trenches 27, 47 can be removed, for example by etching using HF (FIG. 3B).

The next step is to form a protective layer 69 on the front face of the substrate 1, based on a material designed to resist etching of the infill material 66 of the cavities 31, 51. For example, this protective layer 69 may be based on silicon nitride or a High-K material such as HfO₂, particularly when the infill material 66 is based on SiO₂. The protective layer 69 covers the infill material 66 located in the trenches 27, 47, and forms protective plugs 69a in the trenches 27, 47 (FIG. 3C).

The trenches lined with the protective layer 69 may then be filled again with the infill material 66, for example SiO₂ (FIG. 3D). Such an infill may be designed to make a plane surface on the front face.

The infill material 66 may then be planarised by CMP planarizing on the front face A of the substrate 1.

The infill material 66 of the cavities is then removed (FIG. 3E). The material 66 is accessible at zones 4, 5 located on a side face of the substrate 1 and in which the cavities 31a, 31b open up. This removal may be made by chemical etching, for example using HF when the material 66 is based on SiO₂. The layer 69 formed previously on the front face A of the substrate acts as protection during the chemical etching. A mask 70 previously formed on the front face may be provided to protect the material formed in the trenches.

Since the tunnel made between lateral zones 4, 5 of the substrate is continuous, this etching can be used to remove a thickness of the support layer 10 on the back face of the substrate 1, particularly over the entire extent of the back face (FIG. 3E).

The trenches previously formed in the cavities are not necessarily all at the same pitch P. A variant embodiment of the examples of methods described above is shown in FIG. 4, and includes adjacent trenches 27, 47, for example spaced either at a first spacing P1 or at a second spacing P2 different from P1 and such that P2>P1, the first trenches 27 being distributed at a pitch P1+P2 and the second trenches 47 are also distributed at a pitch P1+P2.

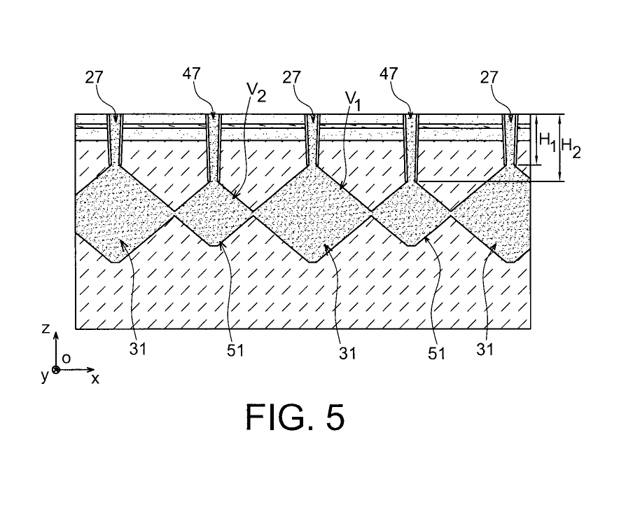

FIG. 5 contains another example embodiment with first trenches 27 and second trenches 47 with different heights H₁, H₂ respectively, for example such that H₁<H₂. In this example, the volume occupied by the cavities is different for each cavity, the first trenches 27 communicating with cavities 31 with a given volume V₁, while the second trenches 47 communicate with cavities 51 with volume V₂ such that V₂<V₁.

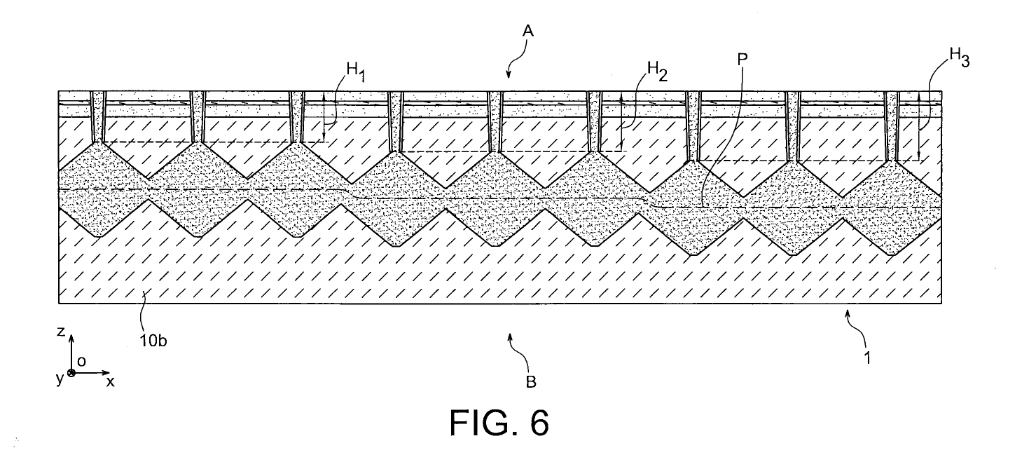

In the example in FIG. 6, cavities communicate with trenches with depths H₁, H₂, H₃, such that the cavities are located at different depths relative to the front face A of the substrate 1.

Adjacent or nearby cavities made in the substrate communicate with each other such that all cavities form a continuous tunnel that extends over the entire area of the substrate 1 (in this case measured in a plane [O;x;y] in FIG. 6). Due to the difference in depth between the cavities, the isolating tunnel makes a stepped profile P.

A portion 10b of the support layer 10 can be removed later from the back face B of the variable thickness substrate 1 and that follows this profile.

Such an embodiment may be applied for example when the microelectronic device that is made from substrate 1 is a photo-detector comprising cells designed to detect different wavelengths, corresponding to different thicknesses of a portion 10a of the substrate to be kept and in which the active layer is located between the front face A and the cavities.

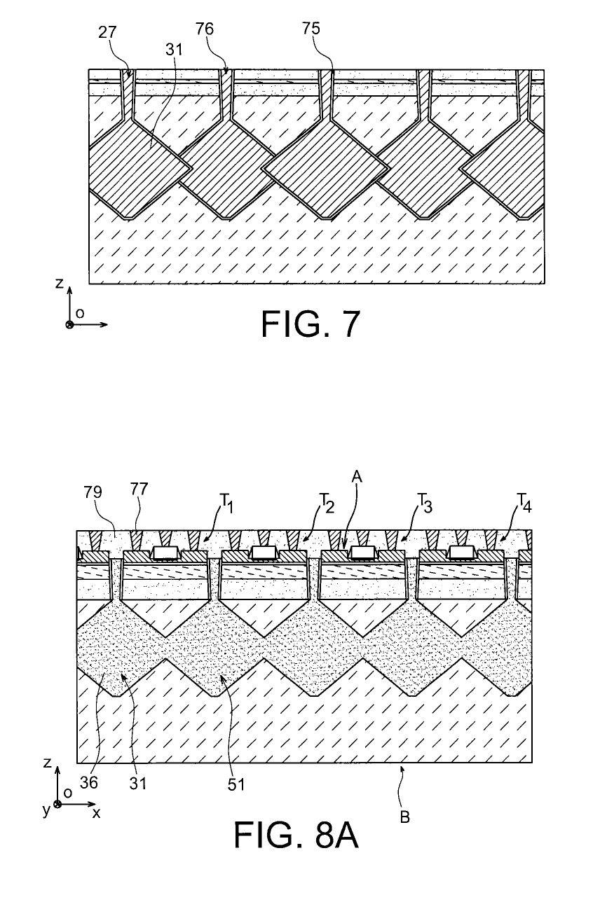

Another variant embodiment is shown in FIG. 7. In this variant, the infill material of the trenches 27 and the cavities 31 is a metallic material 76 for example such as Tungsten, Copper or a conducting material like those used for the infill of TSV (Through Silicon Via) interconnection elements.

In this case, before the trenches 27 and the cavities 41 are filled, a barrier layer 75, for example based on TaN may be formed so as to line the walls of the trenches and the cavities. This barrier layer 75 may prevent metallic diffusion in the substrate 1. Such a variant may enable use of a thinned substrate 1 with a back face covered with metallic material 76.

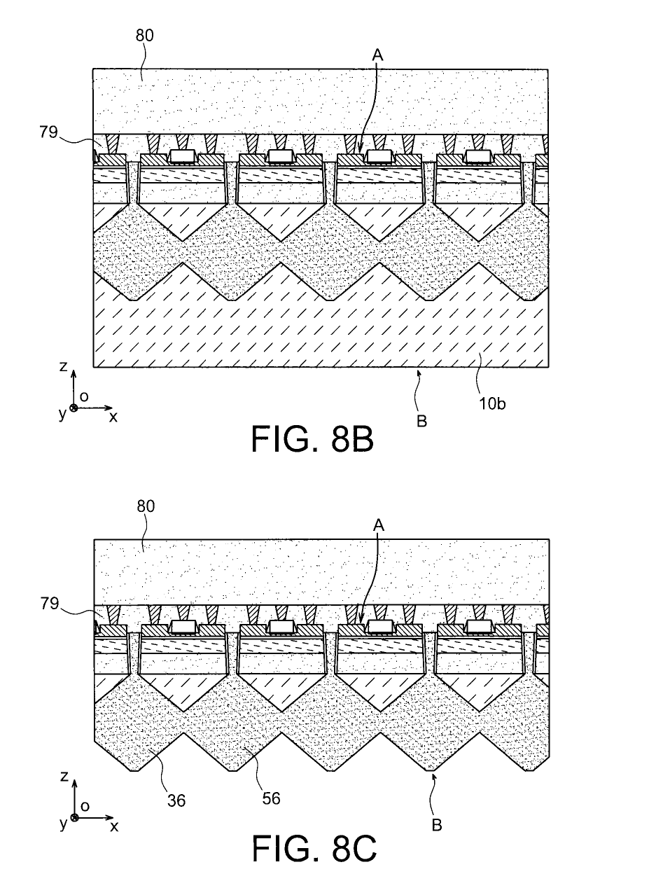

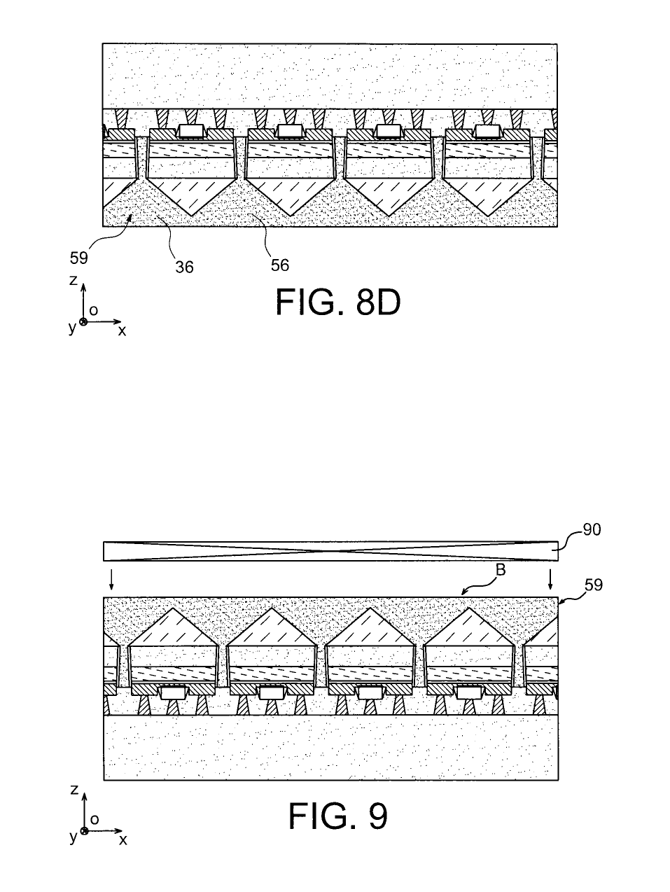

FIGS. 8A-8D illustrate another example of a method according to the invention.

In this example, components are made partly in the semiconducting layer 13 of the substrate 1 forming an active layer, before the step consisting of removing a portion of the substrate 1 through its back face B as described previously with reference to FIGS. 2B-2C or FIGS. 3D-3E. In this example, the components formed on the front face A of the substrate 1 are transistors T₁, T₂, T₃, T₄, on which contacts 77 are provided and formed in a protective layer 79 covering the active layer on the front face A of the substrate 1.

This protective layer 79 is based on a material that may be a dielectric material and is different from the infill material 36, 56 of the cavities 31, 51, preferably a material chosen to be able to resist etching of the infill material 36, 56 of the cavities 31, 51. For example, the protective layer 79 may be based on silicon nitride (SiₓN_{y}) when the cavities 31, 51 are full of SiO₂ (FIG. 8A).

The next step is to attach a handle support 80 to the protective layer 79. This handle support 80 is thus placed on the side of the front face A of the substrate 1 and may for example be based on a polymer material (FIG. 8B).

As a variant, the handle support 80 may be a substrate covered with a silicon oxide layer. In this case, the handle support 80 and the protective layer 79 may be assembled by direct bonding for example such as an oxide/oxide type bonding, in other words an oxide layer placed on the support on an oxide layer formed on the protective layer 79, without any adhesive or intermediate material.

The next step is to remove a portion 10b from the back face B of the substrate 1. It is removed for example by etching and/or by grinding, until the cavity infill material 36, 56 is reached (FIG. 8C).

The next step on the back face B of the substrate 1 is to polish the given cavity infill material 36, 56 so as to form a plane layer 59 based on said given material 36,56, (FIG. 8D).

Then, according to a first possibility, after being made plane, the layer 59 may be assembled with another device 90 such as another support 90, or another substrate 90 that may comprise other components (FIG. 9). The assembly is made using a molecular bonding technique between an SiO₂ layer and another SiO₂ layer (oxide/oxide bonding) between which hydrogen bonds are created.

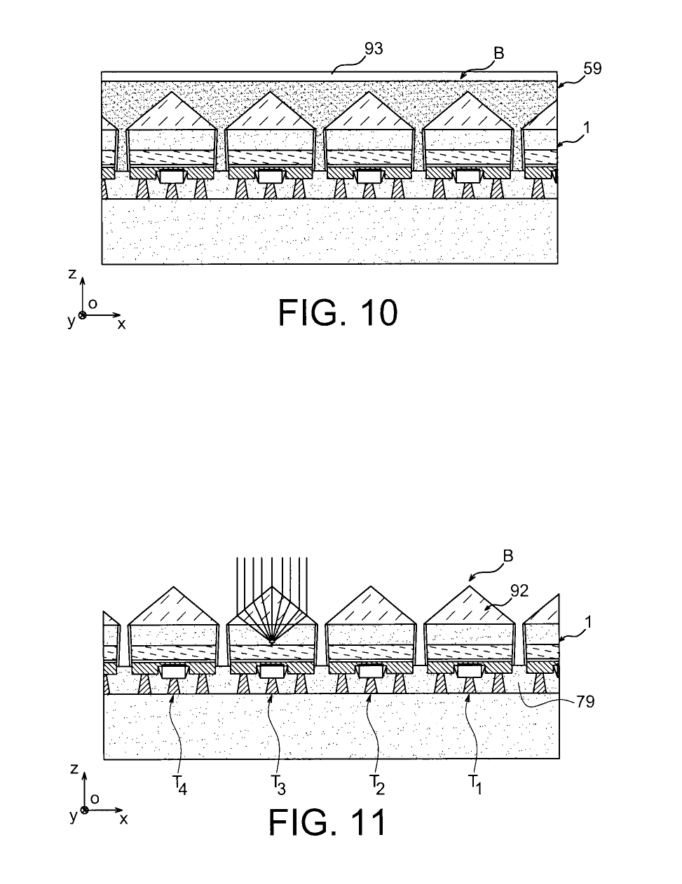

According to another possibility, after planarisation of the back face, one or several layers may be deposited on the layer 59 of material 36, 56 on the back face B of substrate 1. For example, in the case in which the device fabricated on the substrate is of the optoelectronic type and for example comprises photo-detecting cells, an anti-reflection layer 93 may be deposited on the layer 59 that has been made plane (FIG. 10).

According to another possible embodiment (FIG. 11), after the layer 59 has been made plane on the back face B of the substrate 1, or after the step to remove the portion 10b of the substrate described above with reference to FIG. 8C, the infill material 36, 56 can be removed from the trenches and the cavities. This is done by etching this material 36, 56, on the back face B of the substrate 1, stopping on the protective layer 79. Such etching makes it possible to expose the remaining portions of the semiconducting support layer 10 of the substrate 1 in the form of blocks 92 of semiconducting material located facing the components T₁, T₂, T₃, T₄ formed in and on the active layer of the substrate. These remaining blocks 92 may for example be in the form of a pyramid when the cavities 31, 51 are made using a method like that described previously with reference to FIG. 1E.

In one case, for example in which the microelectronic device made is a device with an imager function or an imager circuit, the remaining blocks 92 of the support layer 10 of the substrate 1 may be designed to form dioptres, particularly lenses.

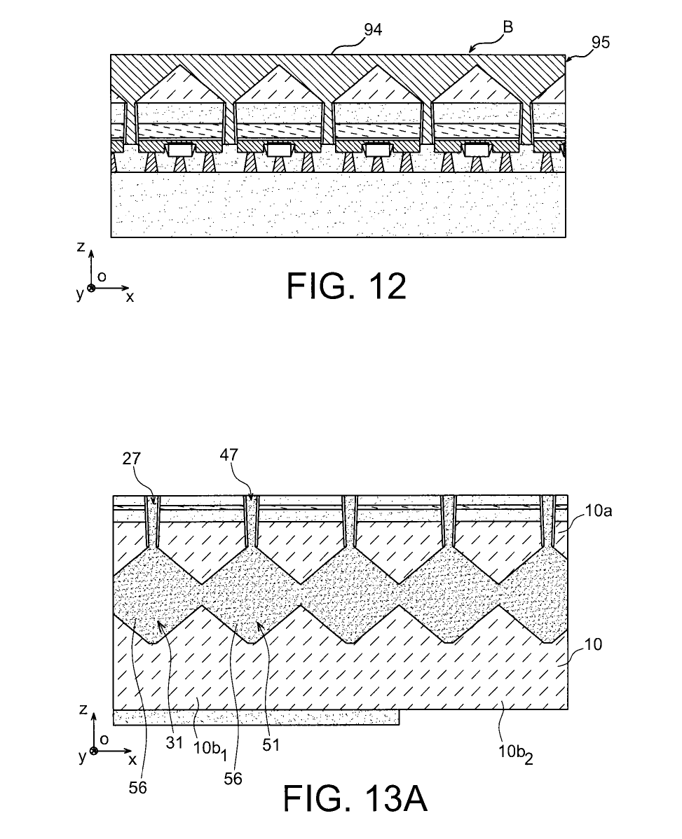

According to one variant shown in FIG. 12, after the step to remove the infill material 36, 56 from the trenches and cavities through the back face B of the substrate 1, it is possible to fill these trenches and these cavities again using another material 94. This other material 94 may be metallic, for example copper. A planarisation step of the metallic material 94 may then be performed, for example by CMP, so as to form a plane layer 95 of metallic material 94 on the back face B of the substrate 1. This layer 95 of metallic material 94 may be designed to be able to make electrical contact on the back face B of the substrate 1. This layer 95 of metallic material 94 may also be used to make an assembly with another device or another support or another substrate, for example by molecular bonding of a metal layer on a metal layer, for example copper/copper molecular bonding.

In each of the examples of methods presented above, a portion 10b of the substrate 1 is removed that extends over the entire surface of the back face B of the substrate, the back face B being entirely exposed after etching.

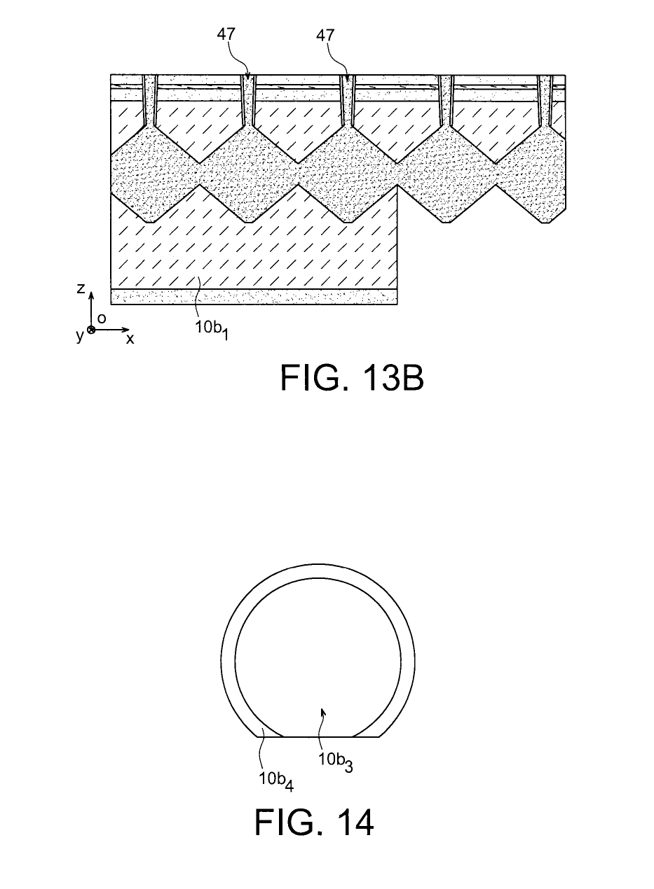

According to one variant shown in FIGS. 13A, 13B, only a local zone on the back face B of the substrate is exposed.

To achieve this, after making the trenches 27, 47 and the cavities 31, 51 filled with material 36, 56, a mask 99 is formed on the back face B of the substrate 1 covering a first region 10b1 of the given portion 10b of the support layer 10, while exposing a second region 10b2 located on the given portion 10b of the support layer 10 (FIG. 13A).

The support layer 10 is then etched on the back face B to remove the second region 10b2 that is not protected by the mask 99. This etching is continued until it reaches the infill material 36, 56 of the cavities 31, 51 (FIG. 13B). The first region 10b1 located at the back face B of the substrate 1 is thus kept intact.

The method according to the invention may thus be used to isolate or separate an active part of a substrate from a support portion, this support portion possibly extending over the entire back face of the substrate or it may be a local zone of the back face of the substrate.

Isolation or separation may thus be done at the scale of a wafer or at the scale of one or several chips on a single wafer, or at the scale of a number of components of a chip.

According to one variant embodiment of the method (FIG. 14), all that is removed is a central portion 10b3 on the back face B of the substrate, using local planarization, for example of the type used in the TAIKO™ type method.

The substrate is then polished on its back face until the cavity infill material is reached, using this infill material as a planarization stop material.

A peripheral zone 10b4 around said central portion forming a ring around the removed central portion is kept and maintains cohesion of the substrate.

The example embodiments given above can also be adapted to substrates other than a semiconductor on insulator type substrate.

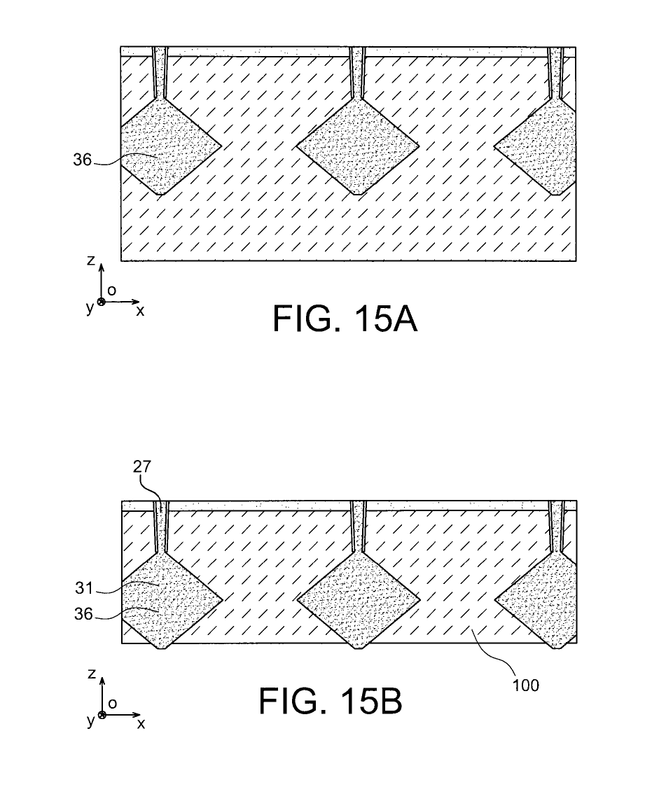

Another example embodiment is shown in FIGS. 15A-15B with a bulk substrate 100 in which the cavities 31 formed along the extension of the trenches 27 are made and filled with a given material 36.

The layout of the trenches 27 and cavities 31 in this example is such that the adjacent cavities are not contiguous with each other (FIG. 15A). The cavities 31 are made to occupy an area measured parallel to the principal plane of the substrate equal to between 20% and 90% of the total area of the back face B of the substrate 100 also measured parallel to the principal plane of the substrate.

In this way, the substrate 100 can be thinned through its back face, for example by planarization and using cavities 31 full of material 36 as planarization stop zones (FIG. 15B).

In particular, the invention has applications in the fabrication of imagers such as UTBB imagers, in other words formed on a substrate comprising an ultra-thin active layer, for example less than 1 μm thick and an ultra-thin insulating layer, for example less than 50 nm thick.

1. A Method for fabricating a microelectronic device comprising steps consisting of:
making a plurality of trenches on the front face of a substrate, comprising an active zone wherein one or several components are provided,
forming cavities wider than the trenches to extend said trenches, such that at least one given cavity formed to extend a given trench, is made adjacent to another cavity formed to extend another trench adjacent to said given trench,
filling said cavities with at least one given material,
the method further including a step consisting of removing at least a given portion of the substrate, based on another material different from said given material and located between its back face, opposite said front face, and said cavities.

2. The method according to claim 1, wherein the step of removing said given portion of the substrate comprises selective etching of said other material of the substrate relative to said given cavity infill material or removal of said other material of the substrate until said given cavity infill material is reached, said given material being an etch stop material.

3. The method according to claim 2, wherein removal of said given portion of the substrate comprises the steps consisting of:
forming a mask protecting a given zone of the back face of the substrate, another zone of the back face being exposed,
etching of this other zone through the mask.

4. The method according to claim 2, in which said given portion of the substrate is a central portion of the substrate, removal being done by planarizing said other material of the substrate until reaching said given infill material that fills the cavities of the substrate, said given material being a planarization stop material, a peripheral zone of the substrate around said central portion being kept.

5. The method according to claim 2, the method further including a step of planarizing said given material on the back face of the substrate after this removal.

6. The method according to claim 5, further including a step after planarization of said given material consisting of depositing at least one layer on the side of the back face of the substrate, particularly an anti-reflecting layer.

7. The method according to claim 5, further including a step after planarisation of said given material, to assemble a support on the back face of said substrate, particularly by molecular bonding.

8. The method according to claim 1, further including a step after removal of said given portion of the substrate to remove said given material.

9. The method for fabricating the microelectronic device according to claim 8, the microelectronic device being an imager wherein the infill material is removed so as to expose blocks of the substrate designed to form lenses.

10. The method according to claim 8, wherein after removing the given material from cavities and trenches, the given material is replaced by a conducting material.

11. The method according to claim 1, wherein one or several of said cavities are formed so as to open up laterally into a zone of a side face of the substrate, such that the given infill material is accessible from this zone, the step for removing said given portion of the substrate including selective etching of the given material relative to said other material of the substrate.

12. The method according to claim 1, wherein said given cavity communicates laterally with said other cavity and forms a tunnel in said substrate with this other cavity, said cavities being filled such that said tunnel is filled with said given material and forms a separation between said active zone and said given portion of the substrate.

13. The method of manufacturing a microelectronic device according to claim 12, wherein steps consisting of making said trenches, forming said widened cavities and filling said cavities include the following:
making a first plurality of trenches on the front face of the substrate,
forming first cavities wider than the first trenches to extend said first trenches,
filling in said first cavities using said given material,
making a second plurality of trenches on the front face of the substrate,
forming second cavities wider than the second trenches to extend said second trenches,
filling in said second cavities using said given material.

14. The method according to claim 1, further including the formation of at least one protective layer on the front face of the substrate and closing said trenches after the cavities have been filled using said given material, making it possible to etch the given infill material selectively relative to the material of the protective layer.

15. The method according to claim 1, further including at least annealing to increase the density of the given material after the cavities have been filled and before said portion of the substrate has been removed.

16. The method according to claim 1, further including assembly of a handle substrate on the front face of the substrate after the cavities have been filled and before said portion of the substrate has been removed.

17. The method according to claim 1, wherein said given trench and said adjacent trench have a predetermined spacing p, the cavities being formed by etching the substrate, etching being prolonged such that cavities comprise walls forming a tapered shape, the distance Δ separating the walls being equal to a value such that Δ>p.

18. The method according to claim 1, wherein said portion removed from the substrate is based on Si with ‘(100)’ crystallographic orientation, the cavities being formed by etching along the ‘(111)’ crystallographic plane.

19. The method according to claim 1, wherein the given cavity infill material is a dielectric material.

20. The method according to claim 1, in which the given cavity infill material is a metal, the method further including a step after formation of the cavities and before they are filled, to form a barrier diffusion layer lining the walls of the cavities.

21. The method according to claim 1, wherein several of said cavities are located at different depths in the substrate.
